(19) United States
(12) Patent Application Publication
(10) Pub. No.: US 2024/0258425 A1
(43) Pub. Date: Aug. 1, 2024

(54) SEMICONDUCTOR DEVICE AND METHOD FOR MANUFACTURING THE SAME

(71) Applicant: DENSO CORPORATION, Kariya-city (JP)

(72) Inventor: Hidefumi TAKAYA, Kariya-city (JP)

(21) Appl. No.: 18/632,840

(22) Filed: Apr. 11, 2024

Related U.S. Application Data
(63) Continuation of application No. PCT/JP2022/018860, filed on Apr. 26, 2022.

(30) Foreign Application Priority Data
Nov. 24, 2021 (JP) 2021-190051

(51) Int. Cl. H01L 29/78; H01L 29/06; H01L 29/16; H01L 29/66

(52) U.S. Cl. CPC H01L 29/7813; H01L 29/0603; H01L 29/1608; H01L 29/66734

(57) ABSTRACT

A semiconductor device includes a semiconductor layer, and a trench gate. The semiconductor layer has a drift region of a first conductivity type and a body region of a second conductivity type. The trench gate is disposed in a trench that extends from a first main surface of the semiconductor layer to the drift region through the body region. A side surface of the trench gate is in contact with the body region and the drift region. Of the body region and the drift region, only the body region has a channel region in a portion in contact with the side surface of the trench gate, and the channel region has an impurity concentration lower than an impurity concentration of a portion of the body region further from the side surface of the trench gate.

### CROSS REFERENCE TO RELATED APPLICATIONS

The present application is a continuation application of International Patent Application No. PCT/JP2022/018860 filed on Apr. 26, 2022, which designated the U.S. and claims the benefit of priority from Japanese Patent Application No. 2021-190051 filed on Nov. 24, 2021. The entire disclosures of all of the above applications are incorporated herein by reference.

### TECHNICAL FIELD

The present disclosure relates to a semiconductor device and a method for manufacturing the semiconductor device.

### BACKGROUND

For example, there has been known a semiconductor device in which an impurity concentration of a region in contact with a side surface of a trench gate is reduced. In such a semiconductor device, for example, the impurity concentration of a portion of a p-type body layer in contact with the side surface of the trench gate is reduced, so that a channel resistance is reduced.

### SUMMARY

The present disclosure describes a semiconductor device and a method for manufacturing the semiconductor device. According to an aspect, a semiconductor device includes a semiconductor layer having a first main surface and a second main surface, and a trench gate. The semiconductor layer has a drift region of a first conductivity type and a body region of a second conductivity type that is disposed closer to the first main surface than the drift region. The trench gate is disposed in a trench that extends from the first main surface of the semiconductor layer to the drift region through the body region. A side surface of the trench gate is in contact with the body region and the drift region. Of the body region and the drift region, only the body region has a channel region in a portion in contact with the side surface of the trench gate, and the channel region has an impurity concentration lower than an impurity concentration of a portion of the body region further from the side surface of the trench gate.

### BRIEF DESCRIPTION OF THE DRAWINGS

Features and advantages of the present disclosure will become more apparent from the following detailed description made with reference to the accompanying drawings, in which:

FIG. 1 is a diagram schematically showing a cross-sectional view of a main part of a semiconductor device;

FIG. 2 is a diagram schematically showing a cross-sectional view of a main part of a semiconductor layer in a process for manufacturing the semiconductor device shown in FIG. 1;

FIG. 3 is a diagram schematically showing a cross-sectional view of the main part of the semiconductor layer in a process for manufacturing the semiconductor device shown in FIG. 1;

FIG. 4 is a diagram schematically showing a cross-sectional view of the main part of the semiconductor layer in a process for manufacturing the semiconductor device shown in FIG. 1;

FIG. 5 is a diagram schematically showing a cross-sectional view of the main part of the semiconductor layer in a process for manufacturing the semiconductor device shown in FIG. 1;

FIG. 6 is a diagram showing a relationship between a taper angle of a trench and a channel concentration percentage; and

FIG. 7 is a diagram schematically showing a cross-sectional view of a main part of a semiconductor layer in a process for manufacturing a modification of the semiconductor device of FIG. 1.

### DETAILED DESCRIPTION

In a semiconductor device in which an impurity concentration of a portion in contact with a side surface of a trench gate is reduced, it is conceivable to reduce the impurity concentration of a portion of an n-type drift layer in contact with the side surface of the trench gate, in addition to the impurity concentration of the portion of the p-type body layer in contact with the side surface of the trench gate. According to studies of the inventor of the present disclosure, however, it has been found that such a configuration poses a problem of an increase in drift resistance.

According to an aspect of the present disclosure, a semiconductor device includes a semiconductor layer having a first main surface and a second main surface, and a trench gate. The semiconductor layer has a drift region of a first conductivity type and a body region of a second conductivity type that is disposed closer to the first main surface than the drift region. The trench gate is disposed in a trench that extends from the first main surface of the semiconductor layer through the body region and reaches the drift region. A side surface of the trench gate is in contact with the body region and the drift region. Of the body region and the drift region, only the body region has a channel region in a portion in contact with the side surface of the trench gate, and the channel region has an impurity concentration lower than an impurity concentration of a portion of the body region further from the side surface of the trench gate than the channel region.

In such a semiconductor device, the channel region having the lower impurity concentration is selectively formed only in the body region. Therefore, only a channel resistance can be reduced while suppressing an increase in drift resistance.

According to an aspect of the present disclosure, a method for manufacturing a semiconductor device includes: forming a trench in a semiconductor layer of a first conductivity type to extend from a first main surface to a predetermined depth; and implanting impurity ions of a second conductivity type to a surface layer portion of the semiconductor layer, thereby to form a body region. In the implanting, the impurity ions are implanted to a depth range not deeper than the trench. Further, in the implanting, the impurity ions are implanted so that the impurity ions emitted inside of the trench do not exist in at least a portion of the depth range.

In such a method, when the body region is formed by the implanting the impurity ions, the impurity concentration can be reduced in the portion of the body region in contact with the trench.

Embodiments of the present disclosure will be described hereinafter with reference to the drawings.

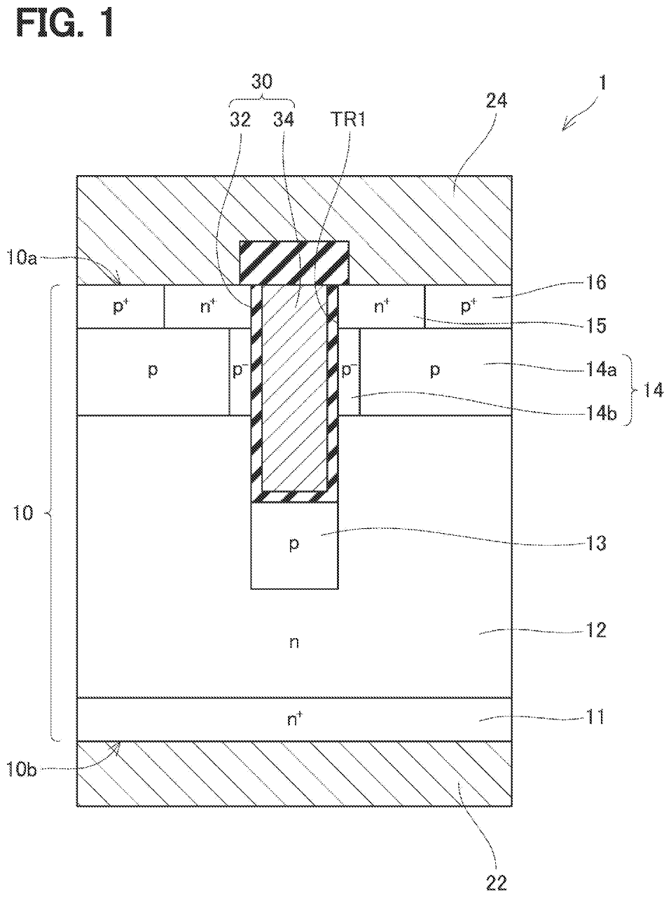

As shown in FIG. 1, a semiconductor device 1 is a semiconductor device of the type of an n-channel metal oxide semiconductor field effect transistor (MOSFET). The semiconductor device 1 includes a semiconductor layer 10, a drain electrode 22, a source electrode 24, and a trench gate 30. The semiconductor layer 10 has a first main surface 10a and a second main surface 10b. The drain electrode 22 covers the second main surface 10b of the semiconductor layer 10, and the source electrode 24 covers the first main surface 10a of the semiconductor layer 10. The trench gate 30 is provided in a front surface layer portion of the semiconductor layer 10. The first main surface 10a and the second main surface 10b are a pair of surfaces extending in parallel, among the surfaces of the semiconductor layer 10. The first main surface 10a and the second main surface 10b are surfaces perpendicular to a thickness direction of the semiconductor layer 10. The semiconductor layer 10 includes an n⁺-type drain region 11, an n-type drift region 12, a p-type electric field relaxation region 13, a p-type body region 14, an n⁺-type source region 15, and a p⁺-type body contact region 16. The material of the semiconductor layer 10 is not particularly limited. For example, the material of the semiconductor layer 10 may be silicon carbide (SiC).

The drain region 11 is provided in a back surface layer portion of the semiconductor layer 10 and contains an n-type impurity at a high concentration. The drain region 11 is provided at a position exposed on the second main surface 10b of the semiconductor layer 10, and is in ohmic contact with the drain electrode 22. The drain region 11 also serves as a base substrate on which a drift region 12 described later is epitaxially grown.

The drift region 12 is provided on the surface of drain region 11. The drift region 12 is arranged between the drain region 11 and the body region 14. The drift region 12 is in contact with both the drain region 11 and the body region 14. The drift region 12 is formed by epitaxial growth from the surface of the drain region 11, and an n-type impurity concentration of the drift region 12 is substantially constant.

The electric field relaxation region 13 is provided on the drift region 12, and in contact with the bottom surface of the trench gate 30. The electric field relaxation region 13 can relieve electric field concentration at the bottom surface of the trench gate 30.

The body region 14 is provided on the surface of the drift region 12. The body region 14 is arranged between the drift region 12 and the source region 15 and between the drift region 12 and the body contact region 16. The body region 14 includes a main body region 14a and a channel region 14b. The main body region 14a is separated from the side surface of the trench gate 30 across the channel region 14b. The main body region 14a is to a portion of the body region 14 on a side far from the side surface of the trench gate 30. The channel region 14b is in contact with the side surface of the trench gate 30. The channel region 14b is a portion of the body region 14 on a side closer to the side surface of the trench gate 30. The channel region 14b has a lower p-type impurity concentration than that of the main body region 14a. When measured along a plane parallel to the main surface of the semiconductor layer 10, the p-type impurity concentration of the main body region 14a is approximately constant, and the p-type impurity concentration of the channel region 14b decreases toward the side surface of the trench gate 30.

The source region 15 is provided in the surface layer portion of the semiconductor layer 10. The source region 15 is arranged on the surface of the body region 14. The source region 15 contains an n-type impurity at a high concentration. The source region 15 is disposed at a position exposed on the first main surface 10a of the semiconductor layer 10, and is in ohmic contact with the source electrode 24.

The body contact region 16 is provided in the surface layer portion of the semiconductor layer 10. The body contact region 16 is arranged on the surface of body region 14. The body contact region 16 contains a p-type impurity at a high concentration. The body contact region 16 is disposed at a position exposed on the first main surface 10a of the semiconductor layer 10, and is in ohmic contact with the source electrode 24.

The trench gate 30 is provided in a trench TR1 that extends from the first main surface 10a of the semiconductor layer 10 to the drift region 12 through the source region 15 and the body region 14. The side surface of the trench gate 30 is in contact with the source region 15, the channel region 14b of the body region 14, and the drift region 12. The bottom surface of the trench gate 30 is in contact with the electric field relaxation region 13. The trench gate 30 includes a gate insulating film 32 and a gate electrode 34. The side surface and the bottom surface of the gate electrode 34 are covered with the gate insulating film 32. Further, the gate electrode 34 is insulated from the source electrode 24 by an interlayer insulating film.

Next, an operation of the semiconductor device 1 will be described. When a positive voltage higher than the voltage of the source electrode 24 is applied to the drain electrode 22 and a positive voltage higher than a threshold voltage is applied to the gate electrode 34, the semiconductor device 1 is turned on. At this time, an inversion layer is formed in the channel region 14b of the body region 14 in contact with the side surface of the trench gate 30. Electrons injected from the source region 15 move to the drift region 12 via the inversion layer of the channel region 14b, so the semiconductor device 1 is turned on. Since the p-type impurity concentration of the channel region 14b is low, the channel resistance is reduced. Note that the n-type impurity concentration of the drift region 12 in contact with the side surface of the trench gate 30 is not reduced. Therefore, the increase in drift resistance is suppressed. In this manner, in the semiconductor device 1, the channel region 14b with a low impurity concentration is selectively formed only in the body region 14 in the portion in contact with the side surface of the trench gate 30. Therefore, only the channel resistance can be lowered while suppressing the increase in the drift resistance. As such, the semiconductor device 1 can have characteristics of low on-resistance.

When the positive voltage applied to the gate electrode 34 falls below the threshold voltage, the inversion layer of the channel region 14b disappears, and the semiconductor device 1 is turned off. When the semiconductor device 1 is turned off, a depletion layer spreads from the junction surface between the drift region 12 and the body region 14 into each of the drift region 12 and the body region 14. Since the body region 14 has the main body region 14a with a high p-type impurity concentration, the main body region 14a is restricted from being completely depleted and punched through when the semiconductor device 1 is turned off. Therefore, the semiconductor device 1 can have characteristics of high avalanche resistance.

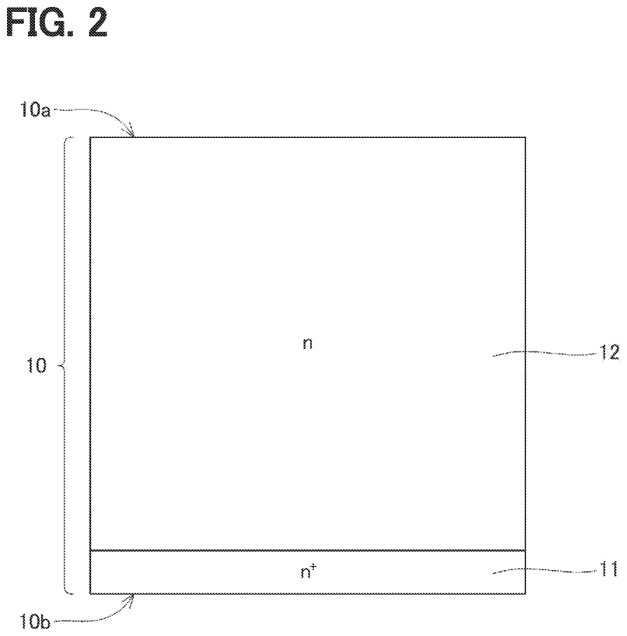

Next, a method for manufacturing the semiconductor device 1 will be explained. First, as shown in FIG. 2, a semiconductor layer 10 in which a drain region 11 and a drift region 12 are stacked is prepared. The semiconductor layer 10 is formed by crystal-growth of the drift region 12 from the drain region 11 using an epitaxial growth technique.

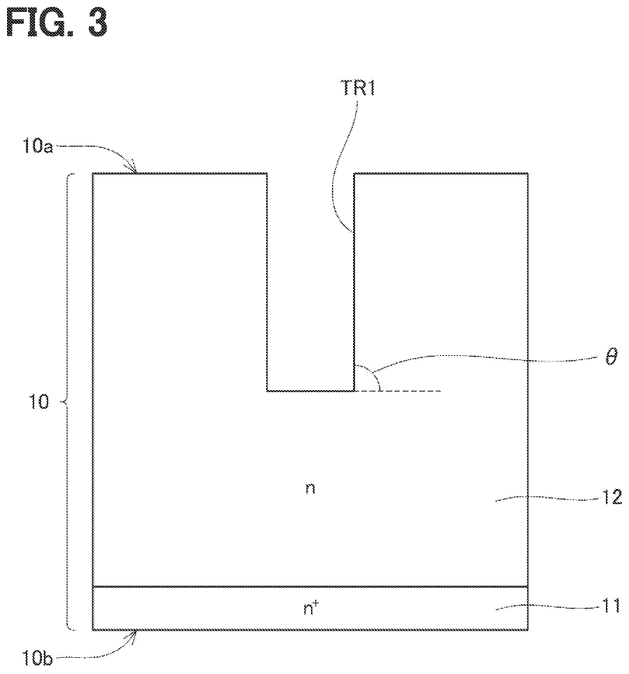

Next, as shown in FIG. 3, a trench TR1 extending from the first main surface 10a of the semiconductor layer 10 to a predetermined depth is formed using a dry etching technique (i.e., an example of a trench forming process). In this case, a taper angle θ of the trench TR1 is defined as an angle between an extension line extending from the end of the bottom surface of the trench TR1 parallel to the bottom surface of the trench TR1 and the side surface of the trench TR1. As will be described later, the trench TR1 is formed so as to have the taper angle θ of 87° or more.

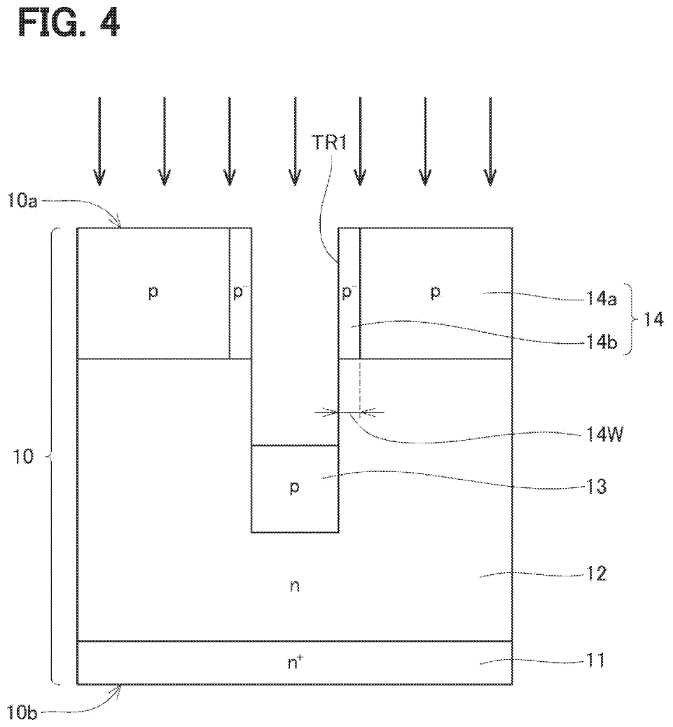

Next, as shown in FIG. 4, p-type impurity ions (for example, aluminum ions) are applied toward the first main surface 10a of the semiconductor layer 10 using an ion implantation technique (i.e., an example of an ion implantation process). Thus, a body region 14 is formed by the p-type impurity ions implanted into the surface layer portion of the semiconductor layer 10 (that is, in a predetermined depth range from the first surface 10a). Further, an electric field relaxation region 13 is formed by the p-type impurity ions that have passed through the trench TR1 and implanted into the bottom surface of the trench TR1.

In this ion implantation process, the p-type impurity concentration of the portion of the body region 14 exposed to the trench TR1 is reduced, so that a channel region 14b is formed. The p-type impurity ions applied toward the inside of the trench TR1 pass through the depth range to be implanted into the semiconductor layer 10 (that is, the predetermined depth range from the first main surface 10a), and are implanted into the bottom surface of the trench TR1. Therefore, in a case where the trench TR1 is not formed, the p-type impurity ions are implanted into a region corresponding to the trench TR1 and are diffused into the channel region 14b. On the contrary, in the manufacturing method of the present embodiment, since such a diffusion of the p-type impurity ions will not occur, the p-type impurity concentration of the channel region 14b is lowered. Further, the p-type impurity ions in the channel region 14b are outwardly diffused into the trench TR1, so that the p-type impurity concentration in the channel region 14b is lowered. For these reasons, the p-type impurity concentration of the portion of the body region 14 exposed on the trench TR1 is selectively reduced, and the channel region 14b is thus formed.

In the ion implantation process, the p-type impurity ions are uniformly applied within the plane of the semiconductor layer 10. Therefore, the p-type impurity concentration at the predetermined depth of the semiconductor layer 10, that is, the p-type impurity concentration at the predetermined depth of the main body region 14a is constant. Therefore, by specifying a region where the p-type impurity concentration is reduced within the plane of the semiconductor layer 10 at the predetermined depth, the position of the channel region 14b can be specified. The width 14 W of the channel region 14b when measured in the direction perpendicular to the side surface of the trench gate 30 may be 10 nm or more and 40 nm or less. When the width 14 W of the channel region 14b is 10 nm or more, an inversion layer can be formed in the channel region 14b, resulting in a decrease in channel resistance. When the width 14 W of the channel region 14b is 40 nm or less, the main body region 14a can be secured widely, so the deterioration of avalanche resistance due to punch-through can be suppressed.

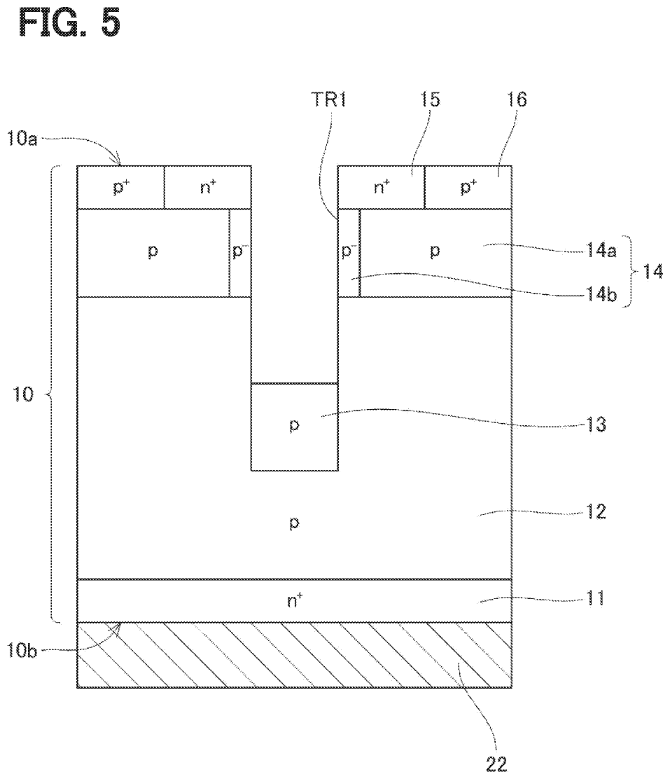

Next, as shown in FIG. 5, using an ion implantation technique, n-type impurity ions (for example, nitrogen ions) and p-type impurity ions (for example, aluminum ions) are implanted into the surface layer portion of the semiconductor layer 10, thereby to form the source region 15 and the body contact region 16. Next, using a chemical vapor deposition (CVD) technique, a gate insulating film 32 and a gate electrode 34 are formed in the trench, thereby to form a trench gate 30 (see FIG. 1). Finally, a drain electrode 22 is formed to cover the second main surface 10b of the semiconductor layer 10, and a source electrode 24 is formed to cover the first main surface 10a of the semiconductor layer 10. In this way, the semiconductor device 1 is produced (see FIG. 1).

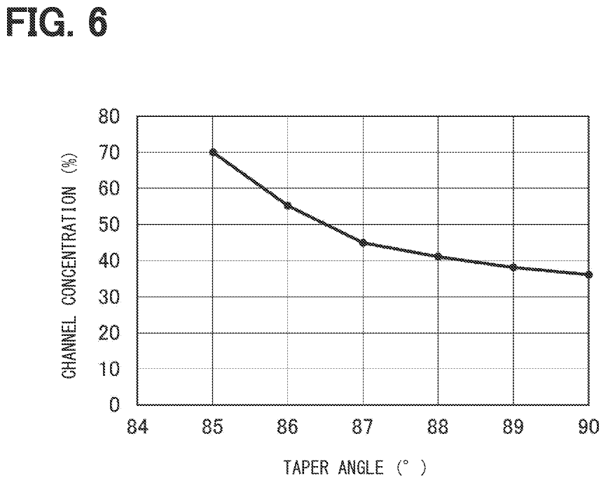

FIG. 6 shows the relationship between the taper angle (θ) of the trench TR1 and the channel concentration percentage of the channel region 14b. The channel concentration percentage is expressed as a percentage of the lowest p-type impurity concentration in the channel region 14b relative to the p-type impurity concentration of the main body region 14a. As shown in FIG. 6, the channel concentration percentage depends on the taper angle (θ) of the trench TR1, and decreases as the taper angle (θ) of the trench TR1 increases. When the taper angle (θ) of the trench TR1 is 87° or more, the channel concentration percentage is 50% or less. That is, the p-type impurity concentration of at least a portion of the channel region 14b can be half or less of the p-type impurity concentration of the main body region 14a.

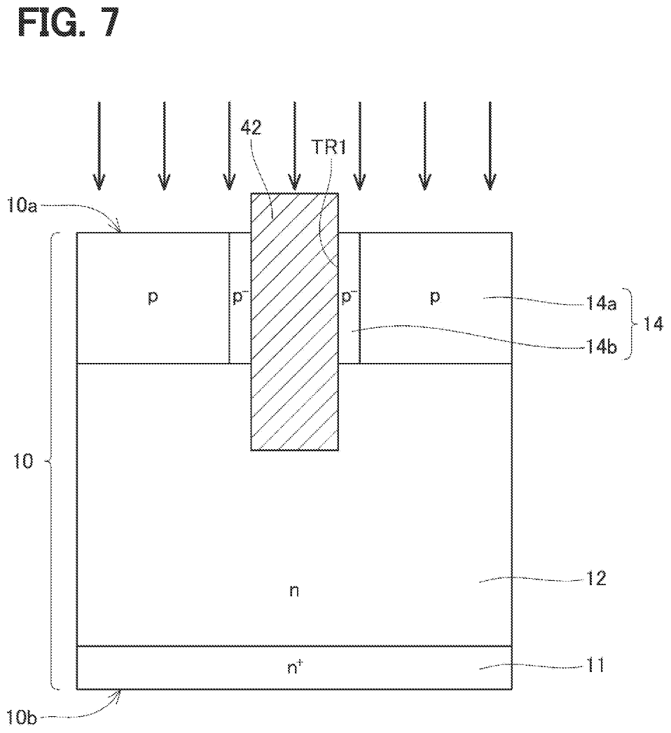

FIG. 7 shows a modification of the ion implantation process. In this example, p-type impurity ions are implanted in a state where the trench TR1 is filled with a shielding material 42. Thereby, it is possible to prevent an electric field relaxation region from being formed on the bottom surface of the trench TR1. The shielding material 42 may be any material that can shield the p-type impurity ions from being implanted at the bottom surface of the trench TR1. For example, the shielding material 42 may be a resist, a silicon oxide film, or a fluid material containing metal. In the case where the shielding material 42 is provided by a resist or a silicon oxide film, the shielding material 42 may be formed so as to protrude from the first main surface 10a of the semiconductor layer 10, as shown in FIG. 7. Also in this example, the p-type impurity ions implanted into the shielding material 42 filling the trench TR1 can be restricted not to be present at least at a part in the depth range of the body region 14. As such, the channel region 14b in which the p-type impurity concentration is selectively lowered can be formed.

The features of the techniques disclosed in the present disclosure are summarized below. It should be noted that the technical elements described below are independent technical elements and exhibit technical usefulness alone or in various combinations, and are not limited to the combinations described in the claims at the time of filing.

In an embodiment, a semiconductor device includes a semiconductor layer having a first main surface and a second main surface, and a trench gate. The semiconductor layer can have a drift region of a first conductivity type and a body region of a second conductivity type disposed closer to the first main surface than the drift region. The trench gate is provided in a trench that extends from the first main surface of the semiconductor layer to the drift region while passing through the body region. A side surface of the trench gate is in contact with the body region and the drift region. Of the body region and the drift region, only the body region has the channel region in a portion that is in contact with the side surface of the trench gate, and the channel region has an impurity concentration lower than an impurity concentration of a portion of the body region farther from the side surface of the trench gate than the channel region.

In an embodiment, in the semiconductor device described above, the impurity concentration of the second conductivity type of at least a part of the channel region may be half or less of the impurity concentration of the second conductivity type of the portion of the body region farther from the side surface of the trench gate. In this case, the semiconductor device can have characteristics of low on-resistance.

In an embodiment, in the semiconductor device described above, the semiconductor layer may further include an electric field relaxation region of the second conductivity type disposed so as to be in contact with a bottom surface of the trench gate. In such a semiconductor device, the electric field concentration at the bottom of the trench gate is alleviated.

In an embodiment, in the semiconductor device described above, the side surface of the trench may have a taper angle of 87° or more.

In an embodiment, in the semiconductor device described above, the channel region may have the width of 40 nm or less, when measured in a direction perpendicular to the side surface of the trench gate. In such a semiconductor device, since the width of the channel region having the low impurity concentration is limited, deterioration of avalanche resistance due to punch-through is suppressed.

In an embodiment, a method for manufacturing a semiconductor device includes a process of forming a trench in a semiconductor layer of a first conductivity type having a first main surface and second main surface; and a process of implanting impurity ions of a second conductivity type to a surface layer portion of the semiconductor layer to form a body region. In the process of forming the trench, the trench is formed to extend from the first main surface to a predetermined depth. In the process of implanting the impurity ions, the impurity ions are implanted to a depth range not deeper than the predetermined depth of the trench. The process of implanting the impurity ions is performed so that the impurity ions emitted toward the inside of the trench are not present in at least a part of the depth range of the semiconductor layer to which the impurity ions are implanted.

In an embodiment, in the process of implanting the impurity ions, a side surface of the trench may be exposed in the depth range of the semiconductor layer in which the impurity ions are implanted. In such a case, the impurity concentration of the portion of the body region exposed to the side surface of the trench can be selectively lowered. Further, in the process of implanting the impurity ions, the impurity ions may also be implanted to the bottom surface of the trench, so that an electric field relaxation region is formed. According to such a method, the body region and the electric field relaxation region can be formed simultaneously.

In an embodiment, in the process of implanting the impurity ions, the trench may be filled with a shielding material. In such a case, only the body region can be formed in the process of implanting the impurity ions.

In an embodiment, in the method of manufacturing the semiconductor device described above, the side surface of the trench may have a taper angle of 87° or more. In such a case, the impurity concentration of the portion of the body region exposed to the side surface of the trench can be set to be half or less of the impurity concentration of the portion of the body region on the side farther from the side surface of the trench.

Although specific examples of the present disclosure have been described in detail above, these are merely examples and do not limit the scope of claims. The techniques described in the claims include various modified examples and modified examples of the specific examples illustrated above. In the embodiments described above, the MOSFET has been described as an example of the semiconductor device. However, the present disclosure is also applicable to other types of semiconductor devices including trench gates, such as an insulated gate bipolar transistor (IGBT). Further, in the embodiments described above, the n-channel type semiconductor device has been described as an example. However, the present disclosure is also applicable to a p-channel type semiconductor device. In addition, the technical elements described in the present specification or the drawings exhibit technical usefulness alone or in various combinations, and are not limited to the combinations described in the claims at the time of filing. In addition, the techniques illustrated in the present specification or the drawings can achieve multiple purposes at the same time, and achieving one of the purposes itself has technical usefulness.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A semiconductor device comprising:
a semiconductor layer having a first main surface and a second main surface; and
a trench gate, wherein
the semiconductor layer includes:
a drift region of a first conductivity type;
a body region of a second conductivity type disposed closer to the first main surface than the drift region,
the trench gate is disposed in a trench that extends from the first main surface of the semiconductor layer to the drift region through the body region,
a side surface of the trench gate is in contact with the body region and the drift region, and
of the body region and the drift region, only the body region has a channel region in a portion that is in contact with the side surface of the trench gate, and
the channel region has an impurity concentration that is lower than an impurity concentration of a portion of the body region farther from the side surface of the trench gate than the channel region.

2. The semiconductor device according to claim 1, wherein
the impurity concentration of the second conductivity type of at least a part of the channel region is half or less of the impurity concentration of the portion of the body region farther from the side surface of the trench gate.

3. The semiconductor device according to claim 1, wherein
the semiconductor layer further includes an electric field relaxation region of the second conductivity type disposed to be in contact with a bottom surface of the trench gate.

4. The semiconductor device according to claim 1, wherein
the side surface of the trench gate has a taper angle of 87° or more relative to a plane extending parallel to a bottom surface of the trench gate.

5. The semiconductor device according to claim 1, wherein
the channel region has a width of 40 nm or less in a direction orthogonal to the side surface of the trench gate.

6. The semiconductor device according to claim 1, wherein
the semiconductor layer is made of silicon carbide.

7. A method for manufacturing a semiconductor device, the method comprising:
forming a trench in a semiconductor layer of a first conductivity type to extend from a first main surface of the semiconductor layer to a predetermined depth; and
implanting impurity ions of a second conductivity type to a surface layer portion of the semiconductor layer in a depth range not deeper than the trench, wherein
the implanting of the impurity ions is performed so as to restrict the impurity ions emitted inside the trench from existing in at least a part of the depth range.

8. The method for manufacturing a semiconductor device according to claim 7, wherein
in the implanting of the impurity ions, a side surface of the trench is exposed in the depth range of the semiconductor layer to which the impurity ions are implanted.

9. The method for manufacturing a semiconductor device according to claim 8, wherein
in the implanting of the impurity ions, the impurity ions are implanted to a bottom surface of the trench to form an electric field relaxation region.

10. The method for manufacturing a semiconductor device according to claim 7, wherein
in the implanting of the impurity ions, the trench is filled with a shielding material.

11. The method for manufacturing a semiconductor device according to claim 7, wherein
a side surface of the trench has a taper angle of 87° or more relative to a plane extending parallel to a bottom surface of the trench.

12. The method for manufacturing a semiconductor device according to claim 7, wherein
the semiconductor layer is made of silicon carbide.
